(19) United States
(12) Patent Application Publication
(10) Pub. No.: US 2014/0305689 A1
(43) Pub. Date: Oct. 16, 2014

(54) EMI ABSORBING SHIELDING CAGE PLUG

(71) Applicant: Molex Incorporated, Lisle, IL (US)

(72) Inventor: Jeffrey A. Reeves, North Little Rock, AR (US)

(73) Assignee: Molex Incorporated, Lisle, IL (US)

(21) Appl. No.: 14/252,955

(22) Filed: Apr. 15, 2014

Related U.S. Application Data
(60) Provisional application No. 61/812,324, filed on Apr. 16, 2013.

(51) Int. Cl. H05K 9/00

(52) U.S. Cl. CPC H05K 9/0018
USPC 174/354

(57) ABSTRACT

A plug for a shielding cage is disclosed and the plug has a unitary body that may be molded as a single piece. The plug has a plug body portion and a handle portion that projects away from the plug body portion. The plug body portion has a plurality of spring arms that extend away from a base member and the spring arms are arranged in pairs and each spring arm is biased outwardly to exert an outward force on the walls of the shielding cage into which it is inserted. The plug is formed from an EMI absorbing material so as to eliminate the need for a separate EMI gasket.

### REFERENCE To RELATED APPLICATIONS

The Present Disclosure claims priority to prior-filed U.S. Provisional Patent Application No. 61/812,324, entitled “EMI Absorbing Shield Cage Plug,” filed on 16 Apr. 2013 with the United States Patent And Trademark Office. The content of the aforementioned Patent Application is incorporated in its entirety herein.

### BACKGROUND OF THE PRESENT DISCLOSURE

The Present Disclosure relates generally to shielding cages and small form pluggable connector assemblies, and more particularly, to an improved plug for selectively closing off preselected shielding cages and preventing the egress of electromagnetic interference (“EMI”) therefrom.

Many electronic systems utilize small form pluggable connectors to join two electronic devices together. These pluggable connectors typically take the form of receptacle connectors and receive a mating blade therein which takes the form of a circuit, or edge, card mounted in an electronic module. The connectors are mounted to a circuit board and are surrounded by a shielding cage that defines a hollow, module-receiving bay into which the electronic module is inserted. The cages may be arranged in a single row along the edge of a mother board and the cage openings may extend into an opening formed in a faceplate or bezel. Not all of the module-receiving bays are used in some applications and it is desirable to close off the open bays of the cages in order to prevent the ingress of dust and to prevent the egress of EMI.

Accordingly, plugs have been developed that have a therefore that is inserted into the cage opening. These plugs are expensive to manufacture in that they include a body portion and a separate EMI gasket that is attached the plug member body portion. The body portion is additionally plated which adds an additional step of labor and cost. It is therefore desirable to develop a plug that is lower cost and better suited for plugging the opening of a shielding cage.

The Present Disclosure is therefore directed to an improved plug member for closing off an opening of a shielding cage that is particularly suitable for preventing the egress of EMI from the interior of the shielding cage and which is cost-effective to manufacture.

### SUMMARY OF THE PRESENT DISCLOSURE

Accordingly, there is provided a plug member sized to reliably fit within the opening of a shielding cage, and which absorbs excess EMI, while having a structure that is low cost.

In accordance with an embodiment described in the following Present Disclosure, a plug is provided that includes a unitary member that has a plug portion and a handle portion. The handle portion permits a user to easily insert and remove the plug from the opening of a shielding cage. The plug portion is preferably injection molded from a material that absorbs EMI and as such, may include bits of metal interspersed throughout a resin. The plug portion has a base portion that provides a sealing wall for sealing off the opening of an associated shielding cage opening. A plurality of pairs of spring arms are disposed on the base portion and each spring arm extends in a cantilevered fashion out from the plug base portion. The spring arms have a wave-like configuration that biases them slightly outwardly so that each such spring arm exerts an outward force on the adjacent, opposing cage wall that defines part of the opening of the shielding cage.

The spring arms, as noted above, each preferably include what may be considered as a wavelike configuration that defines a nonlinear path extending from the base portion, rearwardly to free ends of the spring arms. Peaks of these waves define contact surfaces for the plug. The contact surfaces of the spring arms are arranged in pairs so that the spring arms exert contact forces on the opposing walls of the shielding cage opening. The contact force exerted by the spring arm portions holds the plug in place within the opening of the cage and the contact surfaces define grounding points that block EMI form exiting the cage.

These and other objects, features and advantages of the Present Disclosure will be clearly understood through a consideration of the following detailed description.

### BRIEF DESCRIPTION OF THE FIGURES

The organization and manner of the structure and operation of the Present Disclosure, together with further objects and advantages thereof, may best be understood by reference to the following Detailed Description, taken in connection with the accompanying Figures, wherein like reference numerals identify like elements, and in which:

FIG. 1 illustrates a frontal perspective view of a ganged shielding cage assembly in which two cage plugs constructed in accordance with the Present Disclosure have been inserted in two respective openings of the cages;

FIG. 2 is the same view as FIG. 1, but with one plug removed and the other plug partially withdrawn from its shielding cage opening;

FIG. 3A is a frontal perspective view of one of the cage plugs of FIG. 1;

FIG. 3B is a rear perspective view of the cage plug of FIG. 3A;

FIG. 4 is a side elevational view, in section, of a cage plug inserted into the shielding cage assembly of FIG. 1; and

FIG. 5 is a top plan view, in section, of the cage plugs of FIG. 1, inserted in place within the respective openings of the shielding cage assembly.

### DESCRIPTION OF THE PREFERRED EMBODIMENTS

While the Present Disclosure may be susceptible to embodiment in different forms, there is shown in the Figures, and will be described herein in detail, specific embodiments, with the understanding that the Present Disclosure is to be considered an exemplification of the principles of the Present Disclosure, and is not intended to limit the Present Disclosure to that as illustrated.

As such, references to a feature or aspect are intended to describe a feature or aspect of an example of the Present Disclosure, not to imply that every embodiment thereof must have the described feature or aspect. Furthermore, it should be noted that the description illustrates a number of features. While certain features have been combined together to illustrate potential system designs, those features may also be used in other combinations not expressly disclosed. Thus, the depicted combinations are not intended to be limiting, unless otherwise noted.

In the embodiments illustrated in the Figures, representations of directions such as up, down, left, right, front and rear, used for explaining the structure and movement of the various elements of the Present Disclosure, are not absolute, but relative. These representations are appropriate when the elements are in the position shown in the Figures. If the description of the position of the elements changes, however, these representations are to be changed accordingly.

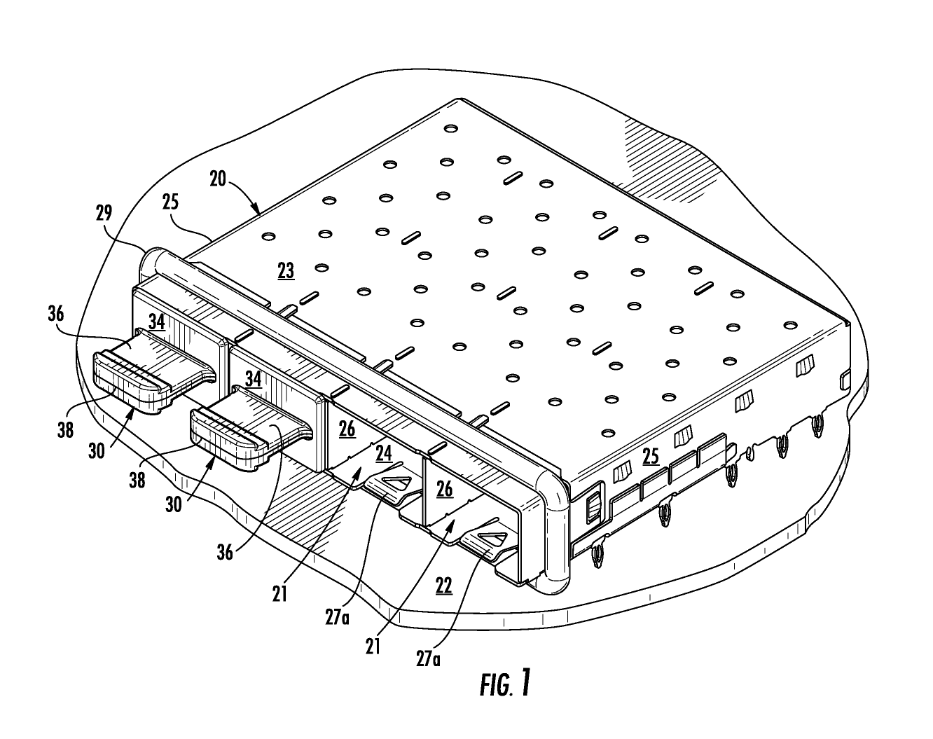

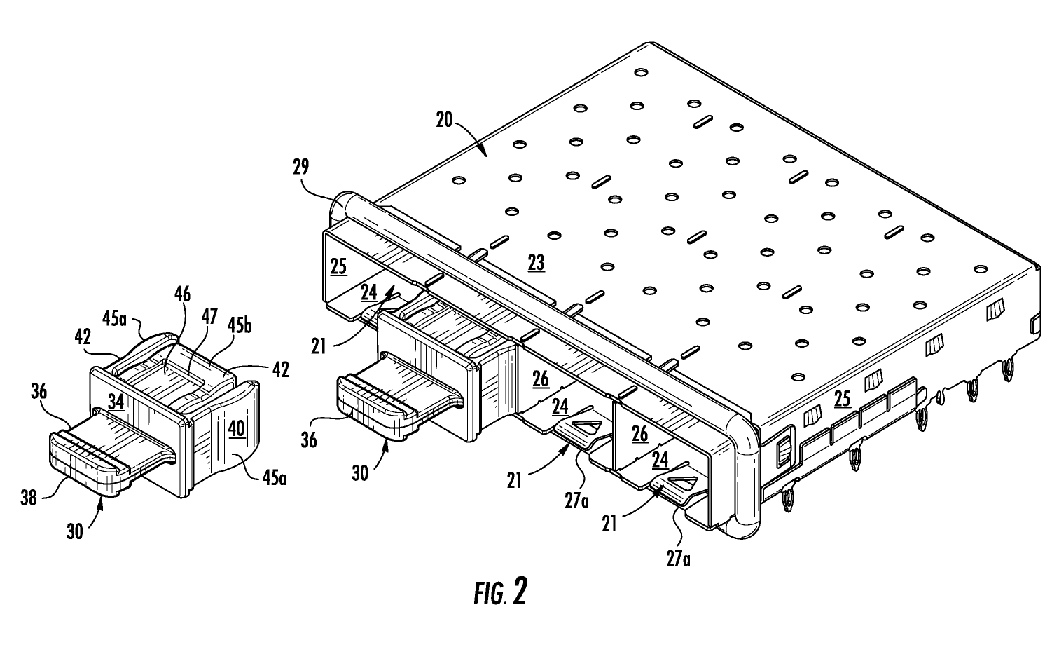

FIG. 1 illustrates a ganged shielding cage assembly 20 formed of a conductive sheet metal and which has four distinct hollow interiors, or bays 21. The shielding cage assembly 20 is typically mounted to a circuit board 22 and placed within an electronic device such as a router, server, switch or the like. The cage assembly 20 has four module-receiving bays 21, each such bay 21 being defined by a plurality of sidewalls, including a top wall 23, bottom wall 24, side walls 25 and inner walls 26. The walls 23-26 cooperatively define an opening 28 at the front of the cage assembly and each such opening 28 is associated with a respective cage 27 of the cage assembly 20. Each such cage 27 defines a respective module-receiving bay 21 that typically encloses a receptacle connector (not shown) mounted to the circuit board 22 and which is configured to receive an electronic module therein. The assembly 20 may include a conductive gasket 29 that forms a seal between the cages 27 and the device faceplate. The module used with such assemblies 20 typically contains a mating blade in the form of an edge card pushed into mating contact with the enclosed receptacle connector in order to form a connection with circuits on the circuit board. The module is slid into the bay 21 and pushed forward until its mating blade enters a card slot formed in the receptacle connector. The module may be removed from its connection with the receptacle connector by pulling it rearwardly.

As noted above, the shielding cage assembly 20 has a plurality of walls 23-26 that cooperatively define the hollow interiors of the cages 27 that receive the aforementioned modules, as well as define the opening 24 of each cage 27. The electronic devices that utilize such shielding cage assemblies 22 will have the cage assemblies 20 and circuit board 22 disposed proximate to a faceplate or bezel opening and the front ends of the cages 27 will project through the faceplate opening. Each cage assembly 20 has a plurality of module-receiving bays 21 and each bay 21 may receive a module in it. In certain system arrangements, not all of the cages 27 will receive respective modules and the system arrangement may be revised so that modules may be removed from certain cages 27 and inserted in other cages 27. In any event, it is not uncommon for many electronic systems to have cages 27 that are unused and open.

Open cages are prone to create operational problems for electronic systems. In some environments, dust will enter the open cages and collect in the interior on the receptacle contacts in a manner so as to negatively affect the operation of the connectors when a module is eventually mated to it. In high speed data transmission, the open circuits of the unused cages and connectors may radiate EMI and this EMI will exit the cage through the cage opening and may affect the signal transmission through the adjacent or surrounding modules. Thus is it desirable to temporarily close the openings of the unused cages by way of plugs. Plugs utilized currently in the art include an insulative body and one or more conductive gaskets or skirts that are stamped and formed from sheet metal to provide points of contact between the plug and the cage opening walls. These multi-piece plugs are expensive to manufacture because they utilize multiple pieces, and the pieces must be assembled, and hence the cost to the user of such plugs is high.

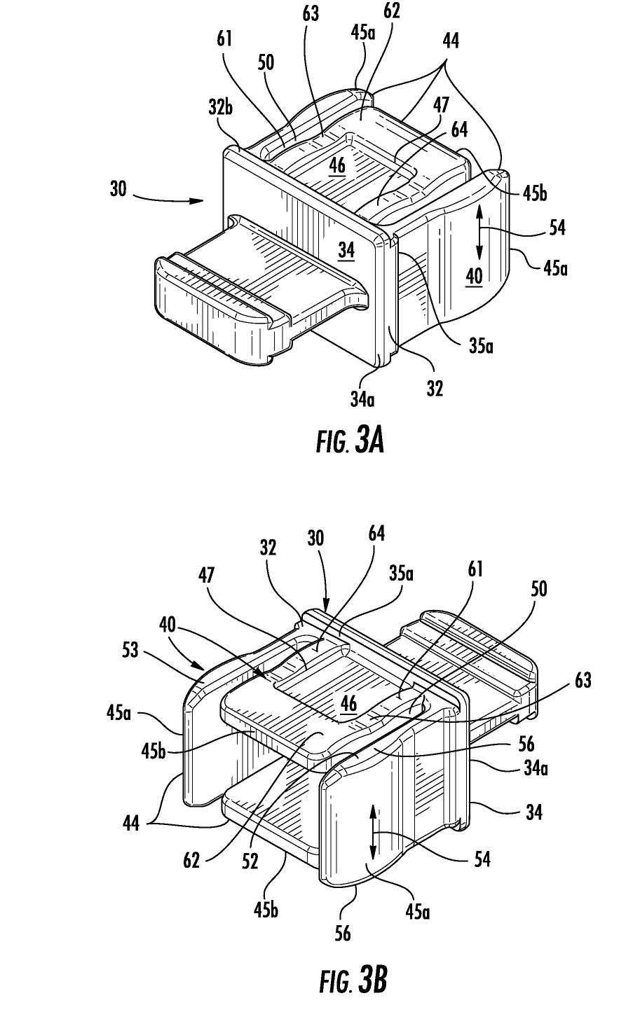

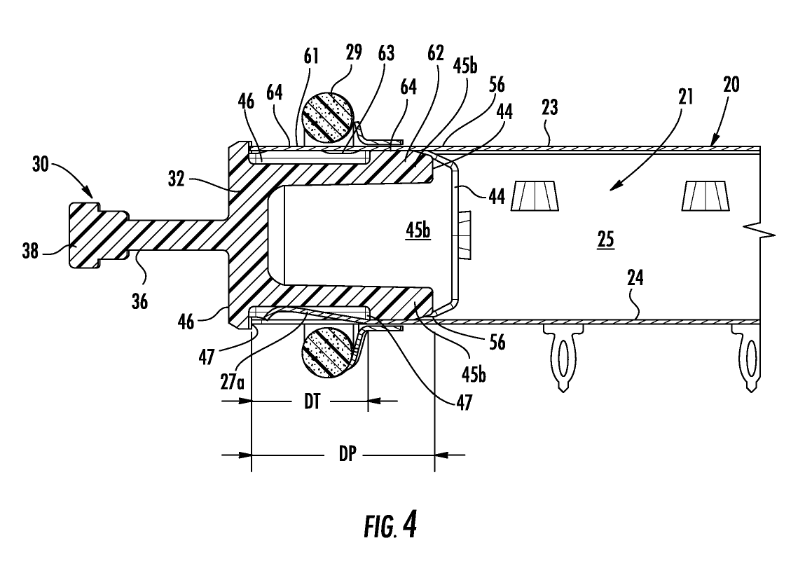

The Present Disclosure describes a unitary and preferably one-piece plug 30 that is used to both cap, or seal off, the opening 28 of an open cage 27, and that prevents the exit of EMI from the interior of the shielding cage 27. In this regard and as shown best in FIGS. 3A-B a plug 30 is provided that includes a body portion 32 with an erect, or upstanding wall portion, or cap member 34 that extends over the shielding cage opening 28 and closes off the opening 28. Hence, the dimensions of the cap member 34 are preferably large enough to cover the cage opening 28 and the rear side 35 of the body portion 32 may include a rim 35a which engages the front edges of the cage walls 23-26 at the opening 28. In order to facilitate inserting the plug into a cage opening and removing it therefrom, the plug 30 includes a handle portion 36 that extends rearwardly from the plug body portion 32 and cap member 34. The handle portion 36 may have an enlarged end 38 to facilitate grasping by a user.

In order to effectively engage the sidewalls and inner walls 25, 26 of the cage 27 (as well as the top and bottom walls 23, 24 thereof), the plug body portion 32 includes a plurality of spring members 40 which take the form of cantilevered spring arms 42 that extend rearwardly from the body portion 32 and which terminate in free ends 44. As shown in the Figures, the spring arms 42 are arranged in two pairs 45a, 45b. One pair 45a of the spring arms 42 extend vertically and will engage the side and inner walls 25, 26 of the cage opening 28, while the other pair 45b of spring arms 42 extend horizontally and will engage the top and bottom walls 23, 24 of the cage opening 29 when the plug 30 is inserted therein. The length, or depth DP of the other pair 45b of spring arms 42 is preferably greater than the depth DT into the cage of the module retaining tab 27a. In order to accommodate and engage this retaining tab 27a, the top and bottom spring arms (other pair 45b) may include recesses 46 disposed therein with an inner shoulder 47 that captures the free end of the retaining tab 27a.

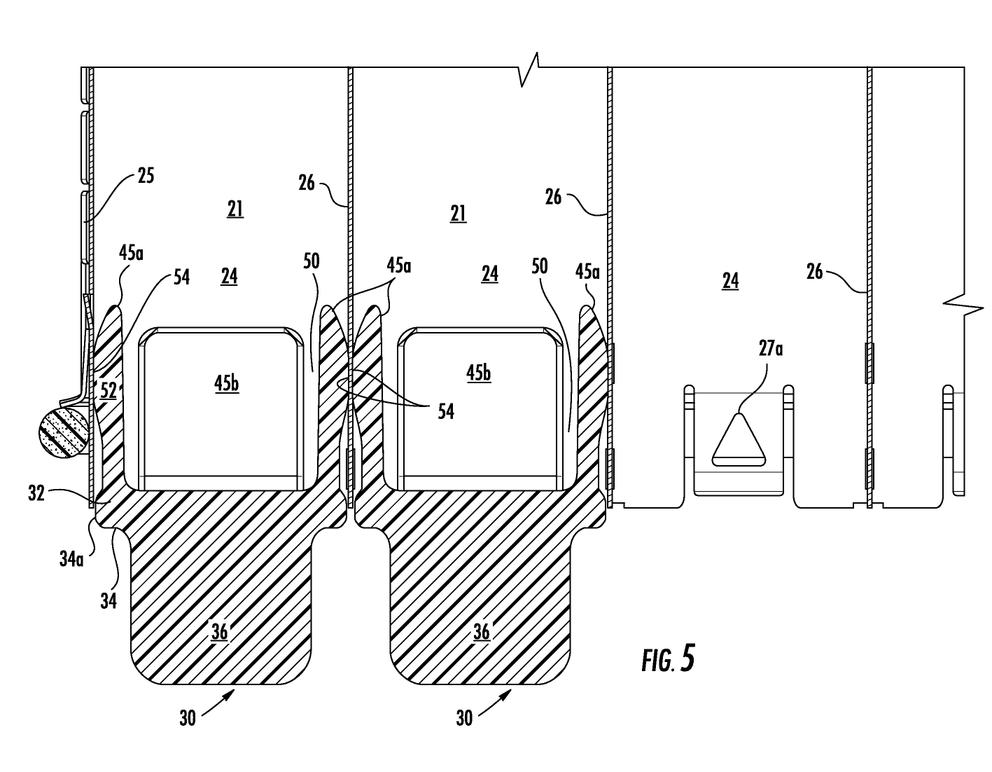

The spring arms 42 are arranged at angles to each other as well as to the plug body portion 32. The pairs of spring arms are separated by intervening spaces 48 which permits them to flex inwardly when inserted into a cage opening 28 and adjacent spring arms are also separated by intervening spaces, such as the slots 50 shown so that each spring arm 42 can move independently during use. The spring arms 42 are further arranged around a perimeter of the plug body portion 32 to ensure engagement with the opposing walls of the shielding cage 27. In order to provide a barrier to EMI occurring during operation of the electronic device, the spring arms 42 have non-linear configuration on their exterior surfaces, i.e., those that oppose the cage walls 23-26. The non-linear configuration shown in the Figures is a wave-like configuration, in which the vertical spring arm pair 45a, as shown in FIGS. 3A and 5, include one wave peak 52 in the form of a curved protrusion 53. This defines a contact surface 54 for the respective spring arm 42 of this pair 45a. Other configurations may be utilized, such as bumps, tabs and the like. It is desirable that the contact surface 54 be continuous in its extent between the top and bottom edges 56 of the spring arms 42 for EMI barrier purposes. It is also preferred that the contact surfaces 54 project past the side edges 34a of the cap member 34 so that the spring arms 42 will deflect slightly when inserted into the cage opening 28 and thereby exert an outward pressure on the side and inner walls of the cage 27. This difference may be seen best in FIG. 5. Because each spring arm 42 is a separate member, they are free to deflect, or flex, inwardly to fit the cage opening yet exert retention pressure on the cage walls 25, 26.

The top and bottom spring arms 42 that form the other pair 45b of spring arms 42 also have a wave-like configuration but as shown in FIGS. 3A-B, such configuration has two wave peaks 61, 62 separated by an intervening valley trough 63. The contact surfaces 64 of this pair 45b lie along the wave peaks 61, 62 but do not extend past the top and bottom edges of the cap member 34 as those edges are desired to extend past the edges of the cage top and bottom walls 23, 24. Nevertheless, the spring arm pair 45b preferably have a width that is slightly greater than the height of the cage opening 28 so that the spring arms 42 thereof will deflect upon insertion and exert a contact or retention force on the cage walls.

In order to provide adequate EMI barrier capabilities, it is desirable that the plug 30 be formed from a conductive, or an EMI absorbing material. Suitable materials may be a die-cast metal, a metallic material, a resin impregnated with conductive particles, a resin impregnated with EMI absorbing materials or even a plated plastic. The structure of the plug 30 is such that it lends itself to being molded as a unitary element, i.e., in one-piece, thereby eliminating assembly costs and the cost of producing a second or third component of an overall multi-piece assembly. It can be seen that the unitary plugs of the Present Disclosure provide cost advantages over the conventional multi-piece plugs.

While a preferred embodiment of the Present Disclosure is shown and described, it is envisioned that those skilled in the art may devise various modifications without departing from the spirit and scope of the foregoing Description and the appended Claims.

What is claimed is:

1. A plug for closing off an opening of a shielding cage in an electronic device and absorbing EMI during operation of the electronic device, the shielding cage including a plurality of walls that cooperatively define a hollow enclosure with an opening into which an electronic module may be inserted, the plug comprising:
a plug body portion, the plug body portion including a cap member for closing off the shielding cage opening and a plurality of spring members extending therefrom, the spring members being arranged in at least one pair of spring members, wherein each pair of spring members is separated by an intervening space, the spring members having a non-linear configuration partially defining at least one contact surface thereon, the contact surfaces being angularly offset from the plug body portion cap member; and
a handle portion, the handle portion being disposed on the plug body portion cap member and extending outwardly therefrom at an angle thereto.

2. The plug of claim 1, wherein the spring members are biased outwardly, such that the contact surfaces thereof engage opposing walls of the shielding cage when the plug in inserted into the shielding cage opening.

3. The plug of claim 1, wherein the plug body portion includes two pairs of spring members, the two pairs of spring members being disposed at an angle to each other.

4. The plug of claim 3, wherein one pair of spring members extend vertically and the other pair of spring members extend horizontally.

5. The plug of claim 2, wherein each spring member includes contact surfaces disposed thereon.

6. The plug of claim 5, wherein each spring member has a wave-like configuration with a least one wave peak, the contact surfaces being disposed along the wave peaks.

7. The plug of claim 6, wherein two of the spring members each include a recess disposed thereon for receiving a retaining tab of the shielding cage.

8. The plug of claim 6, wherein two of the spring members each include a pair of waves.

9. The plug of claim 1, wherein the plug body and handle portion are formed as an unitary member from an EMI absorbing material.

10. The plug of claim 1, wherein the plug is formed from a metallic material, a metallized resin or EMI absorbing material.

11. The plug of claim 3, wherein the spring members extend rearwardly from the plug body portion cap member and terminate in free ends.

12. The plug of claim 3, wherein two of the spring members have their contact surfaces extend past the edges of adjacent ends of the plug body portion cap member.

13. A plug for closing an opening of a shielding cage and preventing leakage of EMI from the shielding cage, the shielding cage including a plurality of walls that cooperatively define a hollow enclosure with an opening into which an electronic module may be inserted, the plug comprising:
a plug body, a cap member disposed on the plug body for closing off the shielding cage opening, the plug body including a plurality of pairs of spring arms extending therefrom and terminating in free ends, the spring arms of each pair being separated by intervening spaces, the spring arms each including at least one contact surface thereon, the spring arm contact surfaces being offset from the cap member;
a handle portion disposed on the cap member and extending outwardly therefrom in a direction opposite that of the spring arms; and
at least the plug body and cap member being formed from a material which absorbs EMI.

14. The plug of claim 13, wherein the spring arms are biased outwardly in a manner so as to exert pressure on the shielding cage walls.

15. The plug of claim 13, wherein the plug body, cap member and handle portion are all formed as one piece.

16. The plug of claim 13, wherein the cap member has two side edges that define a width of the cap member and two of the spring arm contact surfaces extend outwardly past the cap member two side edges to thereby bias the two spring arm contact surfaces into contact with sidewalls of the shielding cage opening.

17. The plug of claim 14, wherein the plug body includes two pairs of spring arms and wherein a first pair of spring arms extend vertically and a second pair of the spring arms extend horizontally.

18. The plug of claim 13, wherein each spring arm has a non-linear configuration with at least one portion disposed thereon that defines a contact surface of the spring arm.

19. The plug of claim 13, wherein the intervening spaces permit the spring arms to flex inwardly when the plug is inserted into the shielding cage opening.

20. A plug for a shielding cage, comprising:
a base, the base including a cap portion large enough to close off an opening of a shielding cage into which the plug is inserted; and
a plurality of spring arms disposed on the base and arranged around a perimeter of the cap portion such that each spring arm contacts an opposing wall of a plurality of walls that define the shielding cage opening, each spring arm extending rearwardly from the base in a cantilevered fashion and pairs of the spring arms being separated by intervening spaces, and including a non-linear configuration which defines at least one contact surface thereon in opposition to a wall of the shielding cage opening.
